(19) United States
(12) Patent Application Publication
(10) Pub. No.: US 2025/0285931 A1
(43) Pub. Date: Sep. 11, 2025

(54) ELECTRONIC PACKAGE WITH INTEGRATED TOP SIDE HEAT SINK

(71) Applicant: Navitas Semiconductor Limited, Dublin (IE)

(72) Inventor: Oseob Jeon, Seoul (KR)

(73) Assignee: Navitas Semiconductor Limited, Dublin (IE)

(21) Appl. No.: 19/074,233

(22) Filed: Mar. 7, 2025

Related U.S. Application Data
(60) Provisional application No. 63/563,269, filed on Mar. 8, 2024.

(51) Int. Cl. H01L 23/367; H01L 21/48; H01L 21/56; H01L 23/00; H01L 23/31; H01L 23/495

(52) U.S. Cl. CPC H01L 23/3677; H01L 21/4821; H01L 21/4875; H01L 21/56; H01L 23/3121; H01L 23/49503; H01L 23/49562; H01L 24/32; H01L 24/48; H01L 24/73; H01L 24/49; H01L 24/83; H01L 2224/32245; H01L 2224/48091; H01L 2224/48245; H01L 2224/49175; H01L 2224/73265; H01L 2224/83224; H01L 2224/83801; H01L 2924/10272

(57) ABSTRACT

An electronic device is disclosed. The electronic device includes a die-attach pad, a semiconductor transistor having: a top surface positioned opposite of a bottom surface; a gate terminal and a source terminal disposed at the top surface; a drain terminal disposed at the bottom surface, a first lead separate from the die-attach pad and including a base, the base electrically and mechanically connected to the die-attach pad, a second lead separate from the die-attach pad and electrically isolated from the die-attach pad, the second lead electrically connected to the gate terminal, and a third lead separate from the die-attach pad and electrically isolated from the die-attach pad, the third lead electrically connected to the source terminal, and an electrically insulative encapsulant at least partially encapsulating the die-attach pad, the semiconductor transistor, the first lead, the second lead and the third lead.

### CROSS REFERENCE TO RELATED APPLICATIONS

This application claims priority to U.S. provisional patent application No. 63/563,269, for “ELECTRONIC PACKAGE WITH INTEGRATED TOP SIDE HEAT SINK” filed on Mar. 8, 2024, which is hereby incorporated by reference in entirety for all purposes.

### FIELD

The described embodiments relate generally to packaged electronics containing one or more semiconductor dies. More particularly, the present embodiments relate to an electronic package with an integrated top side heat sink that provides cooling for the one or more semiconductor dies.

### BACKGROUND

Electronic devices such as computers, servers and televisions, among others, employ numerous packaged semiconductor devices. Some semiconductor devices require specialized electronic packages to accommodate unique physical configurations and performance requirements. New electronic package designs and manufacturing techniques may be required to meet the needs of some semiconductor devices

### SUMMARY

In some embodiments, an electronic device is disclosed. The electronic device includes a metal plate having an interior surface opposite an exterior surface; a semiconductor transistor including: a top surface positioned opposite of a bottom surface; a gate terminal and a source terminal disposed at the top surface; a drain terminal disposed at the bottom surface, wherein the bottom surface of the semiconductor transistor is attached to the interior surface of the metal plate electrically coupling the drain terminal to the metal plate; a drain lead, separate from the metal plate, the drain lead including a base and a pair of opposing fingers extending from the base to respective distal ends, wherein the base is mechanically and electrically connected to the interior surface of the metal plate forming an electrical connection to the drain terminal of the semiconductor transistor, the base positioned on the metal plate adjacent the semiconductor transistor; a source lead, separate from and electrically isolated from the metal plate, the source lead including an interior portion and an exterior portion, the interior portion positioned above the interior surface of the metal plate and positioned adjacent the semiconductor transistor; a source conductor electrically connecting the source terminal to the interior portion of the source lead; a gate lead, separate from and electrically isolated from the metal plate, the gate lead including an interior region and an exterior region, the interior region positioned above the interior surface of the metal plate and positioned adjacent the semiconductor transistor; a gate conductor electrically connecting the gate terminal to the interior region of the gate lead; and an electrically insulative encapsulant at least partially encapsulating the metal plate, the semiconductor transistor, the drain lead, the source lead, the source conductor, the gate lead and the gate conductor, wherein the exterior surface of the metal plate forms a portion of an exterior surface of the electronic device and wherein the opposing fingers of the drain lead extend out of an exterior surface of the electrically insulative encapsulant at a first side surface of the electronic device and wherein the exterior portion of the source lead and the exterior region of the gate lead extend out of the exterior surface of the electrically insulative encapsulant at a second side surface of the electronic device, and wherein the first side surface is opposite of the second side surface.

In some embodiments, the base is connected to the interior surface of the metal plate via a joint that is soldered.

In some embodiments, the base is connected to the interior surface of the metal plate via a joint that is laser welded.

In some embodiments, at least a portion of the exterior surface of the metal plate is exposed.

In some embodiments, the source conductor is wirebonds.

In some embodiments, the electronic device further includes a thermally conductive structure coupled to the exterior surface.

In some embodiments, at least a portion of the thermally conductive structure is exposed.

In some embodiments, a method of forming an electronic device is disclosed. The method includes forming a die-attach pad; providing a semiconductor transistor including: a top surface positioned opposite of a bottom surface; a gate terminal and a source terminal disposed at the top surface; a drain terminal disposed at the bottom surface; attaching the bottom surface of the semiconductor transistor to the die-attach pad electrically coupling the drain terminal to the die-attach pad; forming a first lead that is separate from the die-attach pad; electrically coupling the first lead to the die-attach pad, wherein the first lead has a portion disposed at a first side of the electronic device; forming a second lead that is separate from and electrically isolated from the die-attach pad; connecting the second lead to the gate terminal, wherein a portion of the second lead is disposed adjacent a second side of the electronic device, wherein the first side of the electronic device is opposite the second side of the electronic device; forming a third lead that is separate from and electrically isolated from the die-attach pad; connecting the third lead to the source terminal, wherein the third lead is disposed at the second side of the electronic device; and forming an electrically insulative encapsulant around at least a portion of each of the die-attach pad, the semiconductor transistor, the first lead, the second lead and the third lead.

In some embodiments, the method further includes coupling a thermally conductive structure to a top surface of the die-attach pad.

In some embodiments in the method of forming the electronic device, the first lead is attached to the die-attach pad via a joint that is soldered or laser welded.

In some embodiments in the method of forming the electronic device, the top surface of the die-attach pad forms a portion of an exterior surface of the electronic device.

In some embodiments, an electronic device is disclosed. The electronic device includes a die-attach pad; a semiconductor transistor including: a top surface positioned opposite of a bottom surface; a gate terminal and a source terminal disposed at the top surface; a drain terminal disposed at the bottom surface, wherein the bottom surface of the semiconductor transistor is attached to the die-attach pad electrically coupling the drain terminal to the die-attach pad; a first lead separate from the die-attach pad and including a base, the base electrically and mechanically connected to the die-attach pad, wherein a portion of the first lead is disposed adjacent a first side of the electronic device; a second lead separate from the die-attach pad and electrically isolated from the die-attach pad, the second lead electrically connected to the gate terminal and disposed adjacent a second side of the electronic device, wherein the first side of the electronic device is opposite the second side of the electronic device; and a third lead separate from the die-attach pad and electrically isolated from the die-attach pad, the third lead electrically connected to the source terminal and positioned adjacent the second side of the electronic device; and an electrically insulative encapsulant at least partially encapsulating the die-attach pad, the semiconductor transistor, the first lead, the second lead and the third lead.

In some embodiments, the bottom surface of the semiconductor transistor is attached to a first surface of the die-attach pad.

In some embodiments, a second surface of the die-attach pad forms a portion of an exterior surface of the electronic device.

### BRIEF DESCRIPTION OF THE DRAWINGS

FIG. 1 is a perspective schematic view of an electronic package with an integrated top side plate according to some aspects of the present application;

FIG. 2 shows an exploded view of the electronic package of FIG. 1 according to some aspects of the present application;

FIG. 3 is a schematic showing cross section view of an embodiment of the electronic package of FIG. according to some aspects of the present application;

FIG. 4 illustrates detailed cross section view of an embodiment of the electronic package of FIG. 1 showing separation between the thin leadframe and the thick leadframe according to some embodiments;

FIG. 5 is a bottom plan view of the electronic device of FIG. 1 according to some aspects of the present application; and

FIG. 6 is a simplified flowchart illustrating a method of forming an electronic device of FIG. 1 according to some embodiments of the disclosure.

### DETAILED DESCRIPTION

Certain aspects of the present disclosure relate to an electronic package with an integrated top side plate. The electronic package can be mounted on a printed circuit board (PCB) so that the top side plate faces away from the PCB. The electronic package can include an overhang with legs that facilitate an electrical connection between the top side plate and the PCB. In some examples, the top side plate can be separate from the overhang and the overhang can be soldered or sintered onto the top side plate. Various inventive embodiments are described herein, including methods, processes, systems, devices, and the like.

Terms such as “top”, “bottom”, “up”, or “down” are used herein for illustrative purposes only and do not indicate an absolute orientation of any component or part thereof. For example, a side of a device that directly abuts a surface of a PCB is herein sometimes referred to as a bottom surface, regardless of an overall orientation of a device-PCB assembly. Similarly, a side of the device that is on an opposite side of such a bottom surface, and therefore faces away from the surface of the PCB, is sometimes herein referred to as a top surface, again only indicating an orientation relative to the PCB. The terms up and down are used in a similar sense herein.

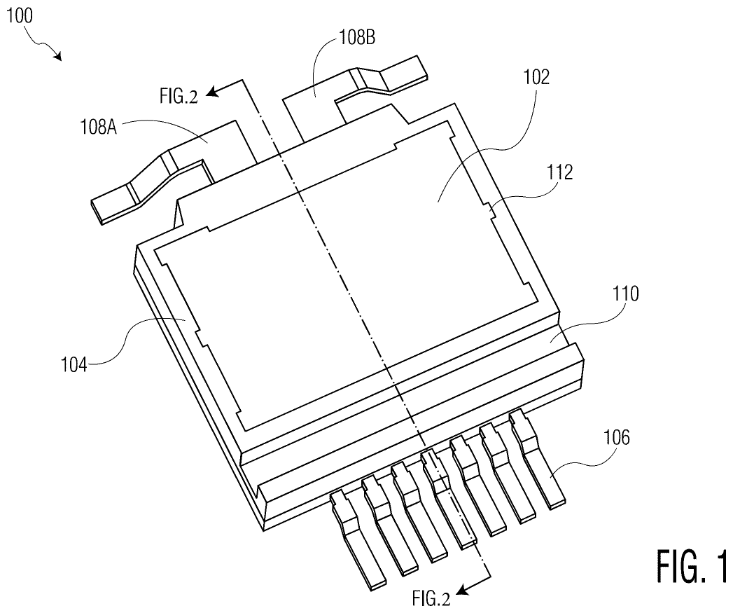

FIG. 1 is a perspective schematic view of an electronic package 100 with an integrated top side plate 102 according to some aspects of the present application. The top side plate 102 can be part of a lead frame for the electronic package 100 and can be made of a metal (e.g. copper), a metal alloy, or other suitable electrically and/or thermally conductive material. The electronic package 100 can include an overhang with leads 108A, 108B. The electronic package 100 can also include a body 104. The body 104 can be an electrically insulative material, such as a resin, formed by molding.

Portions of the electronic package 100 can be exposed and not covered up by the body 104. For example, an upper surface of the top side plate 102 and/or two separate portions of the overhang can be exposed after molding. Having two separate portions of the overhang exposed can reduce thermal and mechanical stress for the electronic package 100. The top side plate 102 can include a region that is thicker than the overhang portion of the top side plate 102 and may be formed via dual-gauge stamping or other suitable process. In some examples, the top side plate 102 can be separate from the overhang and the overhang can be soldered, sintered, welded, or attached via other suitable process to the top side plate 102. The top side plate 102 and separate overhang can be formed of a single material or can be formed from different materials.

A molding process that forms the body 104 can involve locking by molding of the top side plate 102. The locking by molding feature can increase a thermal and mechanical robustness of the top side plate 102. By performing a half etch (e.g., removing a portion of a thickness of the top plate) to portions of a boundary of the top side plate 102, protrusions, such as protrusion 112, can form in the top side plate 102 during the molding process as the mold material fills in portions removed by the half etch. Although six protrusions are shown in FIG. 1, the top side plate 102 can include any number of protrusions, including zero protrusions. For simplicity, only protrusion 112 has a reference number in FIG. 1. The protrusions can assist in securing or locking the top side plate 102 to other components of the electronic package 100, such as to a drain pad. During molding, a trench 110 can be formed in the body 104. The trench 110 can increase the creepage distance between top side plate 102 and pins 106. In some embodiments the creepage distance is a shortest distance between two conductive paths measured along a surface of solid insulation.

The electronic package 100 can also include a semiconductor die (not shown in FIG. 1) such as, for example, a silicon-carbide, gallium nitride, silicon, or gallium arsenide field-effect transistor, or other suitable semiconductor devices. The semiconductor die can be embedded within the electronic package beneath the top side plate 102. Semiconductor dies can often create significant heat when used. An unexposed side or underside of the top side plate 102 can be directly or indirectly attached to the semiconductor die to facilitate heat transfer away from the die. A thermally conductive structure, such as a heatsink, can be thermally coupled to exposed portions of the top side plate 102 (via a thermal interface material or other suitable material) to remove heat from the electronic package 100.

The electronic package 100 can be mounted on a printed circuit board (PCB) so that the top side plate 102 faces away from the PCB. The leads 108A, 108B can facilitate thermal or electrical connection of the top side plate 102 to, for example, the PCB. The electronic package 100 can also include pins, such as pin 106. Although there are seven pins shown in FIG. 1, the electronic package 100 can include any number of pins including zero. For simplicity, only pin 106 is labeled with an element number in FIG. 1. The pins can extend from the body 104 to form electrical connections on one end with the PCB. On another end, the pins can be electrically connected to the semiconductor die 214 by wire bonding, for example.

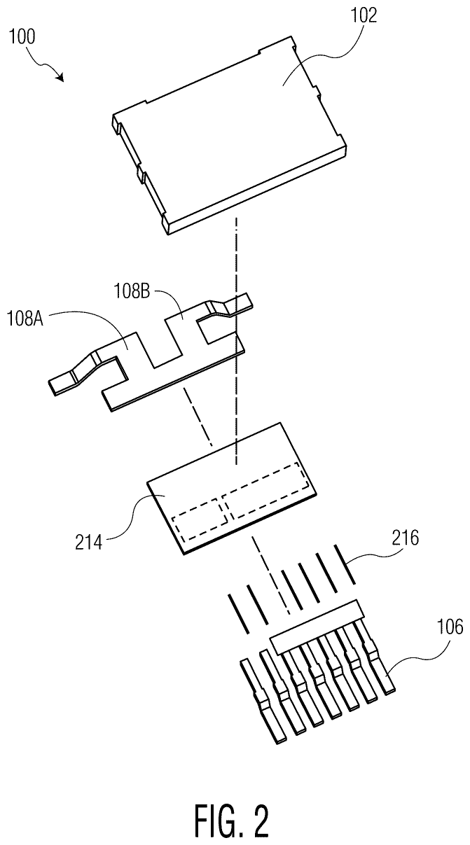

FIG. 2 shows an exploded view of the electronic package 100 with an integrated top side plate according to some aspects of the present application. In the illustrated view, the body 104 is not shown. FIG. 2 shows the semiconductor die 214 embedded within the electronic package 100 positioned beneath the top side plate 102. FIG. 2 further shows wirebonds 216 positioned beneath the semiconductor die 214.

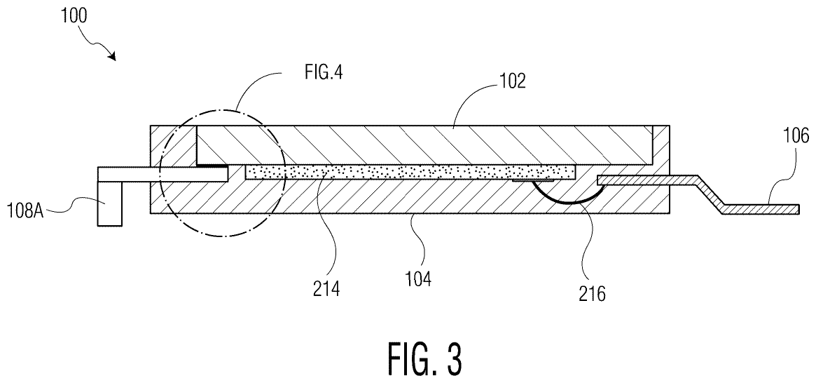

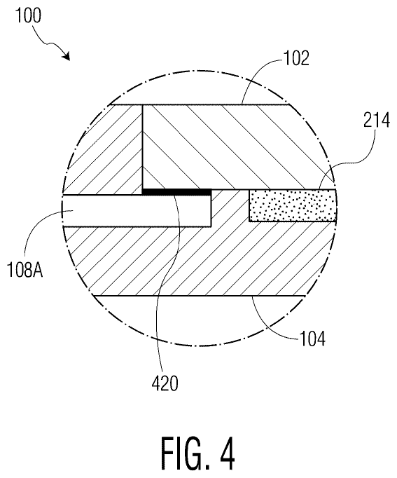

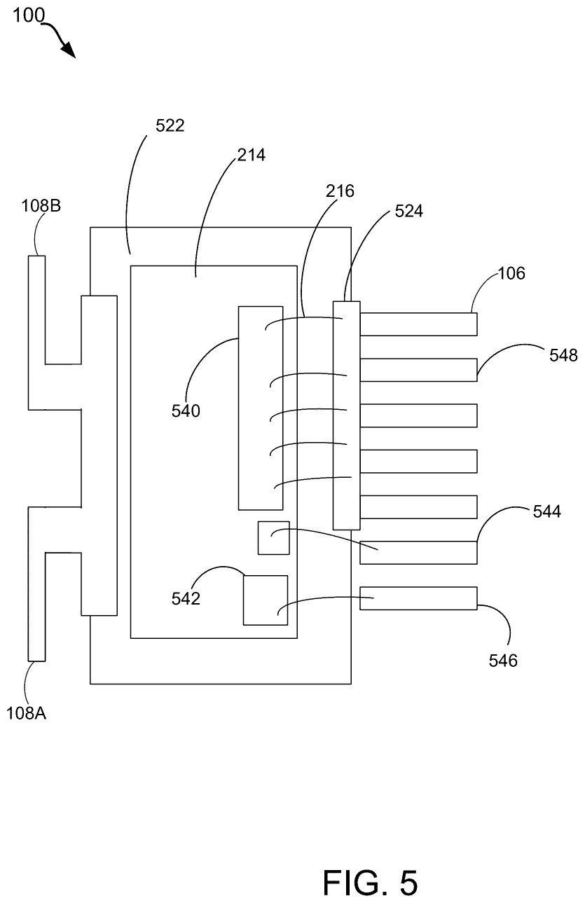

FIG. 3 is a schematic showing cross section view of an embodiment of the electronic package with an integrated top side plate according to some aspects of the present application. Electronic package 100 may be or include any of the components, features, or characteristics of any of the electronic packages previously described. The electronic package 100 can include a separate leadframe design. As shown in the cross-section view of the electronic package 100, the separate leadframe design of the electronic package 100 can include a thick leadframe 102 with a bottom surface attached to a semiconductor die 214. The thick leadframe 102 can also be referred to as the top side plate. The electronic package 100 with a separate leadframe design can also include a thin leadframe 108 that is separate from the thick leadframe 102. The thin leadframe 108 can include leads 108A and 108B. The thin leadframe 108 and the thick leadframe 102 can be formed from an electrically conductive material, such as copper, or different materials, such as different metals, metal alloys, or different electric or thermal conductors. A surface of the thin leadframe can be attached to a portion of the thick leadframe by, for example, soldering, welding, sintering, or other suitable process as illustrated in FIGS. 4 and 5.

FIG. 4 illustrates detailed cross section view of an embodiment of the electronic package with an integrated top side plate showing separation between the thin leadframe and the thick leadframe according to some embodiments. FIG. 4 illustrates the attachment 420 between the thin leadframe 108 and the thick leadframe 102 according to some embodiments. As further shown in FIG. 3, a portion of a top surface of the thin leadframe 108 can be connected to a portion of a bottom surface of the thick leadframe 102 of electronic package 100. In other examples, other surfaces of the thin leadframe 108 can be attached to different surfaces of the thick leadframe 102. For example, a portion of a right-side surface (or the whole right-side surface) of the thin leadframe 108 can be attached to a portion of a left-side surface of the thick leadframe 102. At least a portion of a top surface of the thick leadframe 102 can be exposed after a molding process.

The thin region of electronic package 100 can include a plurality of leads that extend in an opposite direction to the exposed top surface of the thick leadframe and can facilitate an electrical connection of the leadframe to, for example, a PCB. The electronic package 100 can also include pins and each of the pins can be connected to a semiconductor die 214 by, for example, wire bonding, copper clips, flip chip bumps, or other suitable interconnects. The pins can extend in a direction opposite the exposed top surface of the thick leadframe 102 to facilitate additional electrical connections to the PCB. A bottom surface of the thick leadframe 102 of electronic package 100 can be attached to the semiconductor die. The cross-section view illustrates the electronic package 100 after a molding process that can encapsulate the semiconductor die.

In some embodiments, the semiconductor die 214 may be a vertical transistor device such as a silicon carbide field-effect transistor (FET). A drain terminal (e.g., bottom surface) of the transistor may be mechanically and electrically connected to the leadframe, a source terminal may be connected to a plurality of the pins via wirebonds and a gate terminal of the transistor may be connected to one or more of the pins via wirebonds. In some embodiments a kelvin sense pin may be connected to the source terminal in parallel with the source pins. The drain terminal may be electrically connected to the circuit board via the plurality of leads.

FIG. 5 is a bottom plan view of an electronic package 100 with an integrated top side plate according to some aspects of the present application. Electronic package 100 may be or include any of the components, features, or characteristics of any of the electronic packages previously described, and the package may be included in any of the electronic packages as previously discussed. For example, electronic package 100 can include electronic package 100 of FIG. 1 or electronic packages or 100 from FIG. 2. The electronic package 100 can also include a semiconductor die 214. The semiconductor die 214 can be embedded within the electronic package 100 beneath a top side plate and coupled to a die attach pad 522 (DAP). Pins can be electrically connected to the semiconductor die 214. The pins can also be referred to as leads. Although seven leads are shown in FIG. 5, the electronic package 100 can include any number of leads.

The leads can include five common source leads 548, a Kelvin source lead 544, and a gate lead 546. The gate lead 546 can be connected to a gate bonding pad 542 that is positioned on the semiconductor die 214. The Kelvin source lead 544 and the gate lead 546 can be directly connected to the semiconductor die 214 by, for example, wirebonds 216, clip, direct attachment, flip chip, or other suitable connection. Each of the five common source leads can be monolithically formed with the monolithic source wirebond pad 524 or may be attached (e.g., via a solder connection) to the monolithic source wire bond pad. The source wirebond pad 524 may be coupled to a source bonding pad 540 vi wirebonds, clip, direct attachment, flip chip, or other suitable connection. The monolithic source wire bond pad can be insulated from the bottom side of the top side plate via a gap that is filled with mold material. Portions of the monolithic source wire bond pad can be segmented and electrically isolated to accommodate separate electric connections between the semiconductor die and each of the five common source leads. The semiconductor die 214 can be electrically connected to each of the five common source leads via wire bonding connections to segments of the monolithic source wire bond pad. All of the leads can extend from the electronic package 100 to form electrical connections on one end with a PCB.

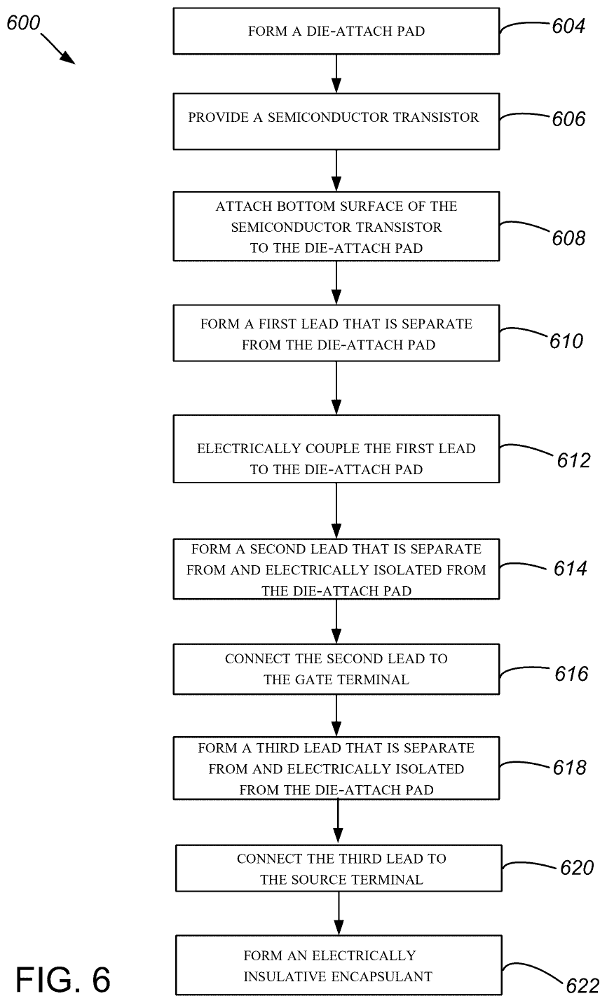

FIG. 6 is a simplified flowchart illustrating a method 600 of forming an electronic device according to some embodiments of the disclosure. As illustrated in FIG. 6, the method of forming an electronic device includes forming a die-attach pad (604). The method also includes providing a semiconductor transistor including: a top surface positioned opposite of a bottom surface; a gate terminal and a source terminal disposed at the top surface; and a drain terminal disposed at the bottom surface (606). The method also includes attaching the bottom surface of the semiconductor transistor to the die-attach pad electrically coupling the drain terminal to the die-attach pad (608). The method further includes forming a first lead that is separate from the die-attach pad (610). Additionally, the method includes electrically coupling the first lead to the die-attach pad, wherein the first lead has a portion disposed at a first side of the electronic device (612). The method further includes forming a second lead that is separate from and electrically isolated from the die-attach pad (614). Additionally, the method includes connecting the second lead to the gate terminal, where a portion of the second lead is disposed adjacent a second side of the electronic device, where the first side of the electronic device is opposite the second side of the electronic device (616). The method further includes forming a third lead that is separate from and electrically isolated from the die-attach pad (618). Additionally, the method includes connecting the third lead to the source terminal, wherein the third lead is disposed at the second side of the electronic device (620). The method further includes forming an electrically insulative encapsulant around at least a portion of each of the die-attach pad, the semiconductor transistor, the first lead, the second lead and the third lead (622).

It should be appreciated that the specific steps illustrated in FIG. 6 provide a particular method of forming an electronic device according to an embodiment of the disclosure. Other sequences of steps may also be performed according to alternative embodiments. For example, alternative embodiments of the disclosure may perform the steps outlined above in a different order. Moreover, the individual steps illustrated in FIG. 6 may include multiple sub-steps that may be performed in various sequences as appropriate to the individual step. Furthermore, additional steps may be added or removed depending on the particular applications. One of ordinary skill in the art would recognize many variations, modifications, and alternatives.

The specification and drawings are, accordingly, to be regarded in an illustrative rather than a restrictive sense. It will, however, be evident that various modifications and changes may be made thereunto without departing from the broader spirit and scope of the disclosure as set forth in the claims.

Other variations are within the spirit of the present disclosure. Thus, while the disclosed techniques are susceptible to various modifications and alternative constructions, certain illustrated embodiments thereof are shown in the drawings and have been described above in detail. It should be understood, however, that there is no intention to limit the disclosure to the specific form or forms disclosed, but on the contrary, the intention is to cover all modifications, alternative constructions and equivalents falling within the spirit and scope of the disclosure, as defined in the appended claims.

The use of the terms “a” and “an” and “the” and similar referents in the context of describing the disclosed embodiments (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening. The phrase “based on” should be understood to be open-ended, and not limiting in any way, and is intended to be interpreted or otherwise read as “based at least in part on,” where appropriate. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate embodiments of the disclosure and does not pose a limitation on the scope of the disclosure unless otherwise claimed. No language in the specification should be construed as indicating any non-claimed element as essential to the practice of the disclosure.

Disjunctive language such as the phrase “at least one of X, Y, or Z,” unless specifically stated otherwise, is otherwise understood within the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present. Additionally, conjunctive language such as the phrase “at least one of X, Y, and Z,” unless specifically stated otherwise, should also be understood to mean X, Y, Z, or any combination thereof, including “X, Y, and/or Z.”

Preferred embodiments of this disclosure are described herein, including the best mode known to the inventors for carrying out the disclosure. Variations of those preferred embodiments may become apparent to those of ordinary skill in the art upon reading the foregoing description. The inventors expect skilled artisans to employ such variations as appropriate, and the inventors intend for the disclosure to be practiced otherwise than as specifically described herein. Accordingly, this disclosure includes all modifications and equivalents of the subject matter recited in the claims appended hereto as permitted by applicable law. Moreover, any combination of the above-described elements in all possible variations thereof is encompassed by the disclosure unless otherwise indicated herein or otherwise clearly contradicted by context.

All references, including publications, patent applications, and patents, cited herein are hereby incorporated by reference to the same extent as if each reference were individually and specifically indicated to be incorporated by reference and were set forth in its entirety herein.

What is claimed is:

1. An electronic device comprising:
a metal plate having an interior surface opposite an exterior surface;
a semiconductor transistor including:
a top surface positioned opposite of a bottom surface;
a gate terminal and a source terminal disposed at the top surface;
a drain terminal disposed at the bottom surface, wherein the bottom surface of the semiconductor transistor is attached to the interior surface of the metal plate electrically coupling the drain terminal to the metal plate;
a drain lead, separate from the metal plate, the drain lead including a base and a pair of opposing fingers extending from the base to respective distal ends, wherein the base is mechanically and electrically connected to the interior surface of the metal plate forming an electrical connection to the drain terminal of the semiconductor transistor, the base positioned on the metal plate adjacent the semiconductor transistor;
a source lead, separate from and electrically isolated from the metal plate, the source lead including an interior portion and an exterior portion, the interior portion positioned above the interior surface of the metal plate and positioned adjacent the semiconductor transistor;
a source conductor electrically connecting the source terminal to the interior portion of the source lead;
a gate lead, separate from and electrically isolated from the metal plate, the gate lead including an interior region and an exterior region, the interior region positioned above the interior surface of the metal plate and positioned adjacent the semiconductor transistor;
a gate conductor electrically connecting the gate terminal to the interior region of the gate lead; and
an electrically insulative encapsulant at least partially encapsulating the metal plate, the semiconductor transistor, the drain lead, the source lead, the source conductor, the gate lead and the gate conductor, wherein the exterior surface of the metal plate forms a portion of an exterior surface of the electronic device and wherein the opposing fingers of the drain lead extend out of an exterior surface of the electrically insulative encapsulant at a first side surface of the electronic device and wherein the exterior portion of the source lead and the exterior region of the gate lead extend out of the exterior surface of the electrically insulative encapsulant at a second side surface of the electronic device, and wherein the first side surface is opposite of the second side surface.

2. The electronic device of claim 1, wherein the base is connected to the interior surface of the metal plate via a joint that is soldered.

3. The electronic device of claim 1, wherein the base is connected to the interior surface of the metal plate via a joint that is laser welded.

4. The electronic device of claim 1, wherein at least a portion of the exterior surface of the metal plate is exposed.

5. The electronic device of claim 2, wherein the source conductor is wirebonds.

6. The electronic device of claim 1, further comprising a thermally conductive structure coupled to the exterior surface.

7. The electronic device of claim 6, wherein at least a portion of the thermally conductive structure is exposed.

8. A method of forming an electronic device, the method comprising:
forming a die-attach pad;
providing a semiconductor transistor including:
a top surface positioned opposite of a bottom surface;
a gate terminal and a source terminal disposed at the top surface;
a drain terminal disposed at the bottom surface;
attaching the bottom surface of the semiconductor transistor to the die-attach pad electrically coupling the drain terminal to the die-attach pad;
forming a first lead that is separate from the die-attach pad;
electrically coupling the first lead to the die-attach pad, wherein the first lead has a portion disposed at a first side of the electronic device;
forming a second lead that is separate from and electrically isolated from the die-attach pad;
connecting the second lead to the gate terminal, wherein a portion of the second lead is disposed adjacent a second side of the electronic device, wherein the first side of the electronic device is opposite the second side of the electronic device;
forming a third lead that is separate from and electrically isolated from the die-attach pad;
connecting the third lead to the source terminal, wherein the third lead is disposed at the second side of the electronic device; and
forming an electrically insulative encapsulant around at least a portion of each of the die-attach pad, the semiconductor transistor, the first lead, the second lead and the third lead.

9. The method of claim 8, further comprising coupling a thermally conductive structure to a top surface of the die-attach pad.

10. The method of claim 9, wherein at least a portion of the thermally conductive structure is exposed.

11. The method of claim 8, wherein the first lead is attached to the die-attach pad via a joint that is soldered.

12. The method of claim 8, wherein the first lead is attached to the die-attach pad via a joint that is laser welded.

13. The method of claim 8, wherein the top surface of the die-attach pad forms a portion of an exterior surface of the electronic device.

14. An electronic device comprising:
a die-attach pad;
a semiconductor transistor including:
a top surface positioned opposite of a bottom surface;
a gate terminal and a source terminal disposed at the top surface;
a drain terminal disposed at the bottom surface, wherein the bottom surface of the semiconductor transistor is attached to the die-attach pad electrically coupling the drain terminal to the die-attach pad;
a first lead separate from the die-attach pad and including a base, the base electrically and mechanically connected to the die-attach pad, wherein a portion of the first lead is disposed adjacent a first side of the electronic device;
a second lead separate from the die-attach pad and electrically isolated from the die-attach pad, the second lead electrically connected to the gate terminal and disposed adjacent a second side of the electronic device, wherein the first side of the electronic device is opposite the second side of the electronic device; and
a third lead separate from the die-attach pad and electrically isolated from the die-attach pad, the third lead electrically connected to the source terminal and positioned adjacent the second side of the electronic device; and
an electrically insulative encapsulant at least partially encapsulating the die-attach pad, the semiconductor transistor, the first lead, the second lead and the third lead.

15. The electronic device of claim 14, wherein the bottom surface of the semiconductor transistor is attached to a first surface of the die-attach pad.

16. The electronic device of claim 15, wherein a second surface of the die-attach pad forms a portion of an exterior surface of the electronic device.

17. The electronic device of claim 14, wherein the first lead is attached to the die-attach pad via a joint that is soldered.

18. The electronic device of claim 14, wherein the first lead is attached to the die-attach pad via a joint that is laser welded.

19. The electronic device of claim 16, further comprising a thermally conductive structure coupled to the second surface.

20. The electronic device of claim 19, wherein at least a portion of the thermally conductive structure is exposed.
